(19) United States
(12) Patent Application Publication
(10) Pub. No.: US 2019/0284687 A1
(43) Pub. Date: Sep. 19, 2019

(54) Cleaning Method and Operating Method of Film-Forming Apparatus, and Film-Forming Apparatus

(71) Applicant: TOKYO ELECTRON LIMITED, Tokyo (JP)

(72) Inventors: Tatsuya MIYAHARA, Nirasaki City (JP); Masahisa WATANABE, Nirasaki City (JP); Sena FUJITA, Nirasaki City (JP)

(21) Appl. No.: 16/353,213

(22) Filed: Mar. 14, 2019

(30) Foreign Application Priority Data
Mar. 15, 2018 (JP) 2018-048482

(51) Int. Cl. C23C 16/44; H01L 21/02; C23C 16/40; C23C 16/34

(52) U.S. Cl. CPC C23C 16/4405; H01L 21/02164; C23C 16/345; H01L 21/02271; C23C 16/401; H01L 21/0217

(57) ABSTRACT

In a method of cleaning a film-forming apparatus, having a processing container configured to accommodate a substrate therein and to perform film-forming processing in a state in which a pressure-reduced atmosphere is formed therein and a pressure gauge configured to monitor a pressure in the processing container, the method includes supplying a cleaning gas for removing a film formed by the film-forming processing to an inside of the processing container in which the film-forming processing has been performed and to the pressure gauge.

### CROSS-REFERENCE TO RELATED APPLICATION

This application claims the benefit of Japanese Patent Application No. 2018-048482 filed on Mar. 15, 2018 in the Japan Patent Office, the disclosure of which is incorporated herein in its entirety by reference.

### TECHNICAL FIELD

The present disclosure relates to a cleaning method and operating method of a film-forming apparatus, and the film-forming apparatus.

### BACKGROUND

In a film-forming apparatus that carries out film-forming processing by accommodating a substrate in a processing container maintained in a pressure-reduced atmosphere, a film is also deposited on, for example, the inner wall of the processing container by the film-forming processing. When the amount of the film deposited on, for example, the inner wall of the processing container is increased, the film peels off, thus generating particles. Therefore, at a predetermined timing after the film-forming processing, cleaning processing is performed, in which a cleaning gas is supplied into the processing container to remove the film deposited on, for example, the inner wall of the process container.

During film-forming processing, since a film is also deposited on a pressure gauge that monitors the pressure inside the processing container, the detected value of the pressure gauge may be deviated and the pressure inside the processing container may not be normally monitored in some cases. In this case, countermeasures such as replacing the pressure gauge may be considered. However, depending on process conditions, the replacement frequency of the pressure gauge may increase more than before, and reduction of the replacement frequency of the pressure gauge is required.

### SUMMARY

In view of the above, an embodiment of the present disclosure provides a cleaning method of a film-forming apparatus capable of reducing the replacement frequency of a pressure gauge.

In one embodiment, there is provided a method of cleaning a film-forming apparatus, having a processing container configured to accommodate a substrate therein and to perform film-forming processing in a state in which a pressure-reduced atmosphere is formed therein and a pressure gauge configured to monitor a pressure in the processing container, the method including: supplying a cleaning gas for removing a film formed by the film-forming processing to an inside of the processing container in which the film-forming processing has been performed and to the pressure gauge.

In another embodiment, there is provided a method of operating a film-forming apparatus having a processing container configured to accommodate a substrate therein and to perform film-forming processing in a state in which a pressure-reduced atmosphere is formed therein and a pressure gauge configured to monitor a pressure in the processing container, the method including: a film-forming step of forming a film on the substrate by supplying a film-forming gas into the processing container; and a cleaning step of supplying a cleaning gas for removing the film to an inside of the processing container and to the pressure gauge.

In a different embodiment, there is provided a film-forming apparatus including: a processing container configured to accommodate a substrate therein and to perform film-forming processing in a state in which a pressure-reduced atmosphere is formed therein; a pressure gauge configured to communicate with an inside of the processing container via a valve so as to monitor a pressure in the processing container; and a control part configured to control operation of the valve, wherein the control part is configured to control the valve to be in an opened state when supplying a cleaning gas for removing a film formed in the film-forming processing into the inside of the processing container in which the film-forming processing has been performed.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 illustrates an example of a film-forming apparatus according to an embodiment of the present disclosure.

FIG. 2 illustrates an example of an operating method of a film-forming apparatus according to an embodiment of the present disclosure.

FIG. 3 illustrates a relationship between the number of processes and the pressure detected by a pressure gauge.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for carrying out the present disclosure will be described with reference to drawings. In the specification and drawings, constituent elements that are substantially the same will be denoted by the same reference numerals, and redundant descriptions will be omitted.

### [Overall Configuration of Film-Forming Apparatus]

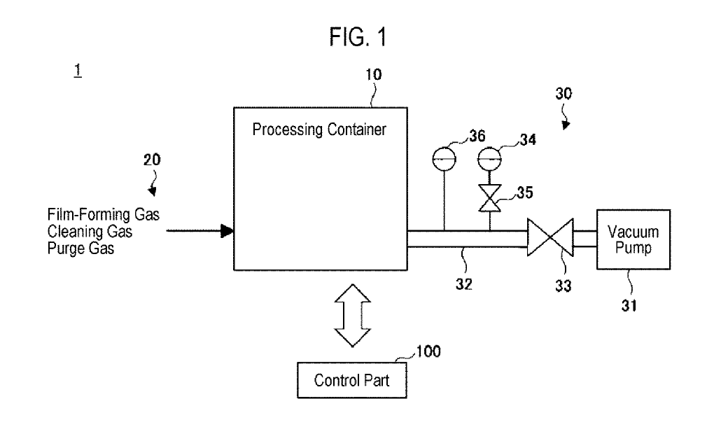

A film-forming apparatus to which a cleaning method according to an embodiment of the present disclosure is applicable will be described. FIG. 1 illustrates an exemplary embodiment of a film-forming apparatus according to an embodiment of the present disclosure.

The film-forming apparatus 1 has a processing container 10, a gas supply part 20, a gas exhaust part 30, and a control part 100. In the film-forming apparatus 1, a gas, the flow rate of which is controlled, is supplied from the gas supply part 20 into the processing container 10, and the gas is exhausted from the gas exhaust part 30, thereby forming a predetermined pressure-reduced atmosphere in the processing container 10, and film-forming processing is performed on a semiconductor wafer (hereinafter, simply referred to as a “wafer”), which is a substrate accommodated in the processing container 10.

In one embodiment, the processing container 10 is a vacuum container configured to perform film-forming processing in the state in which a pressure-reduced atmosphere is formed. The processing container 10 accommodates one or more wafers therein. The processing container 10 may have a mounting table and may be configured to be able to place a single wafer on the mounting table. In addition, the processing container 10 may be provided with a rotary table, and may be configured such that a plurality of wafers can be placed in the circumferential direction of the rotary table. In addition, the processing container 10 may be configured to be able to accommodate, for example, a wafer boat that holds a plurality of wafers in the manner of a shelf.

In another embodiment, the gas supply part 20 supplies various kinds of gases into the processing container 10. The gas supply part 20 has a supply source, a pipe, a flow rate controller, and a valve, which are provided for each kind of gas. Various kinds of gases are supplied from supply sources to the processing container 10 in the state in which the flow rates thereof through pipes are controlled by a flow rate controller. The various kinds of gases may be a film-forming gas, a cleaning gas, and a purge gas. The film-forming gas is a gas used for forming a film on a wafer, and may be a silicon-containing gas. The silicon-containing gas may be monosilane (SiH₄), disilane (Si₂H₆), or diisopropylaminosilane (DIPAS). The cleaning gas is a gas used for removing a film formed in the processing container 10 and on a pressure gauge due to film-forming processing to be described later, and is selected depending on the kind of the formed film. In the case in which the formed film is a silicon-based film, the cleaning gas may be any gas, as long as it can remove the silicon film. For example, fluorine (F₂), chlorine (Cl₂), or chlorine trifluoride (ClF₃) is used. In the case in which the formed film is a silicon oxide film or a silicon nitride film, hydrogen fluoride (HF), a mixed gas of fluorine (F₂) and hydrogen fluoride (HF), or a mixed gas of fluorine (F₂) and hydrogen (H₂) is used as the cleaning gas. The purge gas is a gas used for replacing a film-forming gas and a cleaning gas remaining in the processing container 10, and may be an inert gas such as nitrogen (N₂) or argon (Ar).

In an embodiment, the gas exhaust part 30 exhausts the gas of the processing container 10. The gas exhaust part 30 includes a vacuum pump 31, an exhaust pipe 32, a main valve 33, a first pressure gauge 34, an isolation valve 35, and a second pressure gauge 36. By opening the main valve 33, the gas in the processing container 10 is discharged by the vacuum pump 31 through the exhaust pipe 32. The first pressure gauge 34 communicates with the exhaust pipe 32 via the isolation valve 35, and monitors the pressure in the processing container 10 (the exhaust pipe 32) in the state in which the isolation valve 35 is opened. The first pressure gauge 34 is a pressure gauge having etching resistance to the cleaning gas, and may be a diaphragm vacuum gauge using, for example, Inconel or sapphire as a diaphragm. The measurement pressure range of the first pressure gauge 34 may be, for example, 0 to 1.3 kPa. The second pressure gauge 36 communicates with the exhaust pipe 32, and monitors the pressure in the processing container 10 (the exhaust pipe 32). The second pressure gauge 36 is a pressure gauge having etching resistance to the cleaning gas and is used for measuring a pressure higher than that measured by the first pressure gauge, and may be a diaphragm vacuum gauge using, for example, Inconel or sapphire as a diaphragm. The measurement pressure range of the second pressure gauge 36 may be, for example, 0 to 133 kPa.

The control part 100 controls the operations of respective parts of the film-forming apparatus 1 such as the gas supply part 20 and the gas exhaust part 30. The control part 100 includes a central processing unit (CPU), a read only memory (ROM), and a random access memory (RAM). The CPU executes a desired process according to a recipe stored in a storage region of a RAM. In the recipe, device control information for a process condition is set. The control information may be a gas flow rate, a pressure, a temperature, and a process time. A program used by the recipe and the control part 100 may be stored in a hard disk or a semiconductor memory. In addition the recipe may be set at a predetermined location to be read out in the state of being stored in a storage medium readable by a portable computer such as a CD-ROM or a DVD. In addition, the control part 100 may be provided separately from the film-forming apparatus 1.

### [Operating Method of Film-Forming Apparatus]

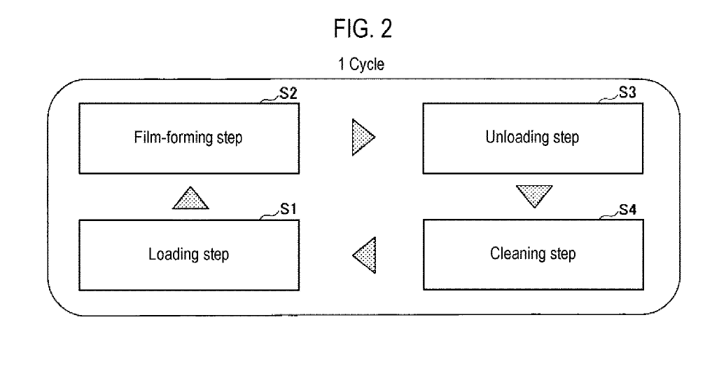

An operating method of a film-forming apparatus according to an embodiment of the present disclosure will be described. FIG. 2 illustrates an exemplary embodiment of an operating method of a film-forming apparatus according to an embodiment of the present disclosure.

As illustrated in FIG. 2, in the operating method of the film-forming apparatus, a loading step S1, a film-forming step S2, an unloading step S3, and a cleaning step S4 form one cycle, and this cycle is repeatedly performed. Further, a purge step may be performed after the film-forming step S2 or after the cleaning step S4.

The loading step S1 is a step of loading a wafer into the processing container 10.

The film-forming step S2 is a step of performing film-forming processing for forming a desired film on a wafer loaded into the processing container 10 in the loading step S1. In the film-forming step S2, in many cases, a film is formed with a pressure of 1.3 kPa or less for the purpose of securing uniformity in film thickness, and in those cases, the pressure inside the processing container 10 is controlled to a desired pressure based on the pressure measured by the first pressure gauge 34 by opening an isolation valve 35. For this reason, in the film-forming step S2, while a film is formed on the surface of a wafer, a film may also be formed on a portion other than the surface of the wafer such as on the inner wall of the processing container 10, the exhaust pipe 32, the first pressure gauge 34, or the second pressure gauge 36. When a film is formed on a portion other than the surface of the wafer and the film becomes thick without being removed, the film peels off and causes particles to be generated.

The unloading step S3 is a step of unloading a wafer having a desired film formed thereon in the film-forming step S2 from the processing container 10.

The cleaning step S4 is a step of supplying a cleaning gas from the gas supply part 20 into the processing container 10 in the state in which no wafer is accommodated and the isolation valve 35 is opened. In the cleaning step S4, since the isolation valve 35 is in the opened state, some of the cleaning gas, which did not react with the film deposited in the processing container 10, reaches the first pressure gauge 34 through the exhaust pipe 32. For this reason, in addition to the inside of the processing container 10, a film deposited on the first pressure gauge 34 may be removed. In addition, since some of the cleaning gas supplied into the processing container 10 reaches the second pressure gauge 36 through the exhaust pipe 32, the film deposited on the second pressure gauge 36 may be removed.

According to the embodiment of the present disclosure described above, after the film-forming gas is supplied into the processing container 10 and a film is formed on the wafer, a cleaning gas is supplied to remove the films deposited in the processing container 10 and on the pressure gauges (the first pressure gauge 34 and the second pressure gauge 36) in the film-forming step S2. As a result, the films deposited on the pressure gauges may be removed simultaneously with chamber cleaning for removing the film deposited in the processing container 10. As a result, it is possible to suppress the occurrence of deviation in detection values of the pressure gauges and to reduce the replacement frequency of the pressure gauges.

Meanwhile, in the conventional cleaning step, in order to shorten the cleaning time, the inside of the processing container is often controlled to have a high pressure of 1.3 kPa or more for cleaning. When a pressure gauge having a measurement pressure range of, for example, 0 to 1.3 kPa is used, the isolation valve is generally set to close at 1.3 kPa, which is the upper limit value of the measurement pressure range. Therefore, cleaning is performed in the state in which the isolation valve is closed. Therefore, even when cleaning is performed, the film deposited on the pressure gauge is not removed.

In one embodiment, the loading step S1, the film-forming step S2, the unloading step S3, and the cleaning step S4 form one cycle and the cycle may be repeated, but the present disclosure is not limited thereto. In another embodiment, the cleaning step S4 may be performed after the loading step S1, the film-forming step S2, and the unloading step S3 are repeated multiple times in this order.

### Example

An example for confirming the effect achieved by the embodiment of the present disclosure will be described.

In this example, one cycle was composed of the loading step S1, the film-forming step S2, the unloading step S3, and the cleaning step S4, and this cycle was repeated. Then, the deviation occurring in the detection value of the first pressure gauge 34 was evaluated by controlling the inside of the processing container 10 to be in a vacuum state by the vacuum pump 31 every cycle and checking the pressure measured by the first pressure gauge 34.

First, in the cycles from the 1^{st} to the 25^{th} cycle, the cleaning step S4 was performed in a state in which the isolation valve 35 was closed. Subsequently, after the completion of the 25^{th} cycle, the isolation valve 35 was opened to perform the cleaning step S4, and the film deposited on the first pressure gauge 34 was removed. Subsequently, in the cycles from the 26^{th} to the 70^{th} cycle, the cleaning step S4 was performed in a state in which the isolation valve 35 was opened.

The conditions of the film-forming step S2 and the cleaning step S4 in the example were as follows. The film-forming step S2 was a step including first film-forming processing (steps S21 to S23), etching processing (step S24), and second film-forming processing (step S25).

<Film-Forming Step S2>

1. Step S21
Kind of gas: DIPAS
Flow rate of gas: 50 to 500 sccm
Temperature of wafer: 350 to 400 degrees C.
Pressure in processing container: 1.0 Torr (133 Pa)

2. Step S22
Kind of gas: Si₂H₆
Flow rate of gas: 50 to 1000 sccm
Temperature of wafer: 350 to 400 degrees C.
Pressure in processing container: 0.5 to 3.0 Torr (67 to 400 Pa)

3. Step S23
Kind of gas: SiH₄
Flow rate of gas: 100 to 2000 sccm
Temperature of wafer: 470 to 530 degrees C.
Pressure in processing container: 0.2 to 3.0 Torr (27 to 400 Pa)

4. Step S24
Kind of gas: Cl₂
Flow rate of gas: 100 to 5000 sccm
Temperature of wafer: 300 to 400 degrees C.
Pressure in processing container: 0.1 to 3.0 Torr (13 to 400 Pa)

5. Step S25
Kind of gas: SiH₄
Flow rate of gas: 100 to 2000 sccm
Temperature of wafer: 470 to 530 degrees C.
Pressure in processing container: 0.2 to 3.0 Torr (27 to 400 Pa)

<Cleaning Step S4>
Kind of gas: N₂ including 20% of F₂
Flow rate of gas: 5 to 20 slm
Temperature of wafer: 300 to 350 degrees C.
Pressure in processing container: 30 Torr (4 kPa)

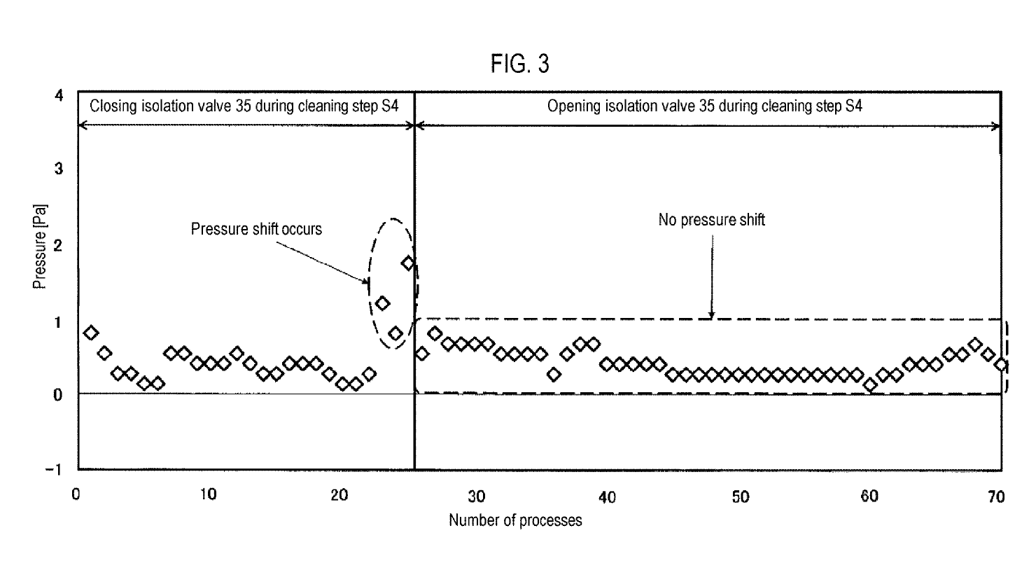

FIG. 3 illustrates the relationship between the number of processes and the pressure detected by a pressure gauge. In FIG. 3, the horizontal axis represents the number of processes and the vertical axis represents the pressure (Pa), which was measured by the first pressure gauge 34 when the inside of the processing container 10 was brought into a vacuum state by the vacuum pump 31.

As illustrated in FIG. 3, when the cleaning step S4 was performed in a state in which the isolation valve 35 was closed, a pressure shift occurred at the 23^{rd} to 25^{th} cycles. In contrast, in the case in which the cleaning step S4 was performed in a state in which the isolation valve 35 was opened, even if the cycle of the loading step S1, the film-forming step S2, the unloading step S3, and the cleaning step S4 was repeated 45 times, no pressure shift was observed.

Therefore, it is believed that, by setting the isolation valve 35 to the open state in the cleaning step S4, even if a film is deposited on the first pressure gauge 34 in the film-forming step S2, the film deposited on the first pressure gauge 34 may be removed. This makes it possible to reduce the replacement frequency of the pressure gauge.

According to the cleaning method of the film-forming apparatus disclosed herein, it is possible to reduce the replacement frequency of a pressure gauge.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of cleaning a film-forming apparatus, having a processing container configured to accommodate a substrate therein and to perform film-forming processing in a state in which a pressure-reduced atmosphere is formed therein and a pressure gauge configured to monitor a pressure in the processing container, the method comprising:
supplying a cleaning gas for removing a film formed by the film-forming processing to an inside of the processing container in which the film-forming processing has been performed and to the pressure gauge.

2. The method of claim 1, wherein the pressure gauge communicates with the inside of the processing container via a valve, and
the cleaning gas is supplied into the processing container in a state in which the valve is opened.

3. The method of claim 1, wherein the pressure gauge has etching resistance to the cleaning gas.

4. A method of operating a film-forming apparatus having a processing container configured to accommodate a substrate therein and to perform film-forming processing in a state in which a pressure-reduced atmosphere is formed therein and a pressure gauge configured to monitor a pressure in the processing container, the method comprising:
a film-forming step of forming a film on the substrate by supplying a film-forming gas into the processing container; and
a cleaning step of supplying a cleaning gas for removing the film to an inside of the processing container and to the pressure gauge.

5. The method of claim 4, wherein the film-forming step and the cleaning step are repeatedly performed.

6. The method of claim 4, wherein the pressure gauge communicates with the inside of the processing container via a valve, and
the cleaning step is performed in a state in which the valve is opened.

7. The method of claim 4, wherein the pressure gauge has etching resistance to the cleaning gas.

8. A film-forming apparatus comprising:
a processing container configured to accommodate a substrate therein and to perform film-forming processing in a state in which a pressure-reduced atmosphere is formed therein;
a pressure gauge configured to communicate with an inside of the processing container via a valve so as to monitor a pressure in the processing container; and
a control part configured to control operation of the valve,
wherein the control part is configured to control the valve to be in an opened state when supplying a cleaning gas for removing a film formed in the film-forming processing into the inside of the processing container in which the film-forming processing has been performed.

9. The film-forming apparatus of claim 8, wherein the pressure gauge has etching resistance to the cleaning gas.
